(19) United States
(12) Patent Application Publication
(10) Pub. No.: US 2025/0197782 A1
(43) Pub. Date: Jun. 19, 2025

(54) RINSE MATERIAL COMPOSITION FOR PATTERNING PROCESS USING LITHOGRAPHY AND PATTERNING METHOD USING THE SAME

(71) Applicant: SAMSUNG ELECTRONICS CO., LTD., Suwon-si (KR)

(72) Inventors: Chawon Koh, Suwon-si (KR); Tsunehiro Nishi, Suwon-si (KR); Jinmo Kim, Suwon-si (KR); Jiyoung Park, Suwon-si (KR); Cheolhong Park, Suwon-si (KR)

(21) Appl. No.: 18/883,523

(22) Filed: Sep. 12, 2024

(30) Foreign Application Priority Data
Dec. 15, 2023 (KR) 10-2023-0183003

(51) Int. Cl. C11D 7/26; G03F 7/00; G03F 7/38; G03F 7/40; H01L 21/027

(52) U.S. Cl. CPC C11D 7/266; C11D 7/261; G03F 7/38; G03F 7/405; G03F 7/70033; H01L 21/0274

(57) ABSTRACT

A rinse material composition used in a process of forming a pattern using lithography includes a dry development rinse material (DDRM) compound and a solvent. The DDRM compound is designed to form hydrogen bonds, van der Waals bonds, coordination bonds, or ionic bonds with photosensitive crosslinkable molecules of a resist pattern. The resist pattern contains an organometallic material. The DDRM compound is dissolved in the solvent.

### CROSS-REFERENCE TO RELATED APPLICATION(S)

This U.S. non-provisional application claims priority under 35 USC § 119 to Korean Patent Application No. 10-2023-0183003, filed on Dec. 15, 2023, in the Korean Intellectual Property Office, the disclosure of which is herein incorporated by reference in its entirety.

### BACKGROUND

Implementations relate to a rinse material composition used in a process of forming a pattern using lithography and a method of forming a pattern using the rinse material composition.

A method of forming a resist pattern and using the formed resist pattern as an etching mask has been widely used to manufacture semiconductor devices. However, as the size of patterns decreases, and especially in line-and-space patterns, the width of the lines and the spacing between the lines decreases significantly, issues such as line width roughness (LWR) and line edge roughness (LER) occur, and a method of forming a resist pattern for reducing such issues is required.

### SUMMARY

Implementations provide a rinse material composition for reducing collapse of a resist pattern to be formed and improving line width roughness and line edge roughness of the resist pattern in a process of forming a pattern using lithography.

Implementations provide a method of forming a pattern using the rinse material composition.

According to an implementation, a rinse material composition used in a process of forming pattern using lithography includes a dry development rinse material (DDRM) compound, designed to form hydrogen bonds, van der Waals bonds, coordination bonds, or ionic bonds with photosensitive crosslinkable molecules containing an organometallic material of a resist pattern, and a solvent in which the DDRM compound is dissolved.

In an implementation, DDRM molecules constituting the DDRM compound may include a body, including a substituted or unsubstituted linear or cyclic hydrocarbon compound having 4 to 100 carbon atoms, and at least one hydrophilic group linked to the body and designed to form hydrogen bonds, van der Waals bonds, coordination bonds, or ionic bonds with the photosensitive crosslinkable molecules.

In an implementation, the hydrophilic group may be at least one of a hydroxyl group, a carboxyl group, a thiol group, an amino group, or an amide group.

In an implementation, the DDRM compound may include at least one of a carboxylic acid, a sulfonic acid, sulfuric acid, a phosphonic acid, a phosphinic acid, a phosphinic acid anhydride, a carboxylate, a phosphonate, an amine, or a thiol.

In an implementation, the substituted or unsubstituted linear or cyclic hydrocarbon compound may include at least one of a carbonyl group and an ether group therein.

In an implementation, the substituted or unsubstituted linear or cyclic hydrocarbon compound may be a dendrimer including at least one of a hydroxyl group and a carboxyl group at an end portion of the body.

In an implementation, the DDRM compound may be contained in an amount of 0.5 weight percent (wt %) to 10 wt % with respect to a total amount of the rinse material composition.

In an implementation, the rinse material composition may further include an additive. The additive may include at least one of a surfactant and a polymeric adsorbent.

In an implementation, the DDRM compound and the additive may be contained in an amount of 0.5 weight percent (wt %) to 10 wt % with respect to a total amount of the rinse material composition.

In an implementation, the DDRM molecules and the additive may constitute a solid, except for the solvent, of the rinse material composition, and the DDRM molecules may be contained in an amount of 0.001 wt % to 99.999 wt % within the solid.

According to an implementation, a method of forming a pattern may include forming a target layer on a substrate, forming a resist layer on the target layer, exposing a first area of the resist layer, developing the resist layer to form a resist pattern in the first area, providing a rinse material composition to the resist pattern, baking the rinse material composition, dry-etching the baked rinse material composition to be removed in a second area, except for the first area, and treating the target layer using the resist pattern as a mask. The resist layer may include photosensitive crosslinkable molecules containing an organometallic material, and the rinse material composition may include a dry development rinse material (DDRM) compound, designed to form hydrogen bonds, van der Waals bonds, coordination bonds, or ionic bonds with the photosensitive crosslinkable molecules, and a solvent in which the DDRM compound is dissolved.

In an implementation, the exposing the first area of the resist layer may be performed using extreme ultraviolet (EUV).

In an implementation, the resist layer may be formed to have a thickness of 100 nanometers (nm) or less.

In an implementation, the method may further include performing a first baking process on the resist layer before the exposing the first area of the resist layer and performing a second baking process on the resist layer after the exposing the first area of the resist layer.

In an implementation, the method may further include performing a cleaning process to clean the resist pattern with a rinse solution after developing the resist layer before providing the rinse material composition.

In an implementation, a height of the rinse material composition may be greater than a height of the resist pattern when the rinse material composition is applied to the resist pattern.

In an implementation, the dry-etching the rinse material composition may be performed using an oxygen-based plasma.

In an implementation, the treating the target layer may be etching the target layer using the resist pattern as a mask.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a flowchart illustrating a method of forming a target pattern having a specific shape according to an implementation.

FIGS. 2A to 2I are cross-sectional views illustrating the method of forming a target pattern based on the order of the flowchart of FIG. 1.

FIG. 3A is a diagram illustrating a profile of a resist pattern after development, FIG. 3B is a diagram illustrating that dry development rinse material (DDRM) molecules in a rinse material composition bond with a surface of a photoresist pattern when the rinse material composition is applied to the resist pattern after the development, and FIG. 3C is a diagram illustrating a profile of the resist pattern after the DDRM molecules bond with the resist pattern.

FIG. 4 is a diagram illustrating a simulation result of a bonding relationship between a solvent and the resist pattern when propylene glycol monomethyl ether acetate (P GMEA) is used as the solvent.

FIGS. 5A to 5C are diagrams illustrating simulation results of a bonding relationship between DDRM molecules and a resist pattern, respectively.

FIG. 6 is a graph illustrating binding energy between the materials used in FIG. 4 and FIGS. 5A to 5C and the resist pattern.

FIGS. 7A and 7B are images captured when a resist pattern is broken or collapsed in a process of forming a resist pattern according to the related art.

### DETAILED DESCRIPTION

Hereinafter, implementations will be described with reference to the accompanying drawings.

Unless otherwise stated, all numbers expressing amounts of ingredients, reaction conditions, or the like, used in this specification and claims are to be understood as being modified by the term “about” in all cases. Therefore, unless otherwise stated, numerical parameters set forth in the specification and appended claims are approximate values that may vary depending on the desired properties to be obtained by the current present disclosure. As used herein, the term “about” when referring to a value or amount of mass, weight, time, volume, concentration, or percentage is intended to include variations from the specified amount in some embodiments of ±20%, in some embodiments of ±10%, in some embodiments of ±5%, in some embodiments of ±1%, in some embodiments of ±0.5%, and in some embodiments of ±0.1%, but to include such variations only when such variations are appropriate for performing the disclosed method.

In addition, the units used in this specification are based on weight, unless otherwise specifically stated. For example, percentage (%) or a unit of ratio refers to weight percent (wt %) or a weight ratio, and wt % refers to weight percent of a single component relative to the total composition, unless otherwise defined.

In addition, the numerical ranges used in this specification include all values between lower and upper limits and within a range thereof, increments logically derived from the form and width of the defined range, all values doubly limited, and all possible combinations of the upper and lower limits of the numerical range limited in different forms. Unless defined specifically in the present specification, values outside the numerical range that may be caused by experimental error or rounding of values are also included in the defined numerical range.

In the present specification, the term “includes” may be used as an open-ended (comprise) expression with the same meaning as the expressions “has,” “contains,” “possesses,” or “features,” and does not exclude elements, materials, or processes not specifically listed. However, the term “includes” may also be a closed-ended (consist of) or partially closed-ended (consist essentially of) expression, depending on the context.

In the present specification, the term “substituted” means that the hydrogen atoms of the substituted moiety are replaced by a substituent. Unless otherwise specified with respect to the substituent, optionally substituted substituents of implementations may include halogen, hydroxyl, alkyl, haloalkyl, mono- or di-alkylamino, aryl, heterocycle, —NO₂, —NRₐ₁R_{b1}, —NRₐ₁C(═O)R_{b1}, —NRₐ₁C(=O)NRₐ₁R_{b1}, —NRₐ₁C(═O)OR_{b1}, —NRₐ₁SO₂R_{b1}, —ORₐ₁, —CN, —C(═O)Rₐ₁, —C(═O)ORₐ₁, —C(=O)NRₐ₁R_{b1}, —OC(═O)Rₐ₁, —OC(═O)ORₐ₁, —OC(═O)NRₐ₁R_{b1}, —NRₐ₁SO₂R_{b1}, —PO₃Rₐ₁, —PO(ORₐ₁)(OR_{b1}), —SO₂Rₐ₁, —S(O)Rₐ₁, —SO(NRₐ₁)R_{b1} (for example, sulfoximine), —S(NRₐ₁)R_{b1} (for example, sulfilimine) or —SRₐ₁, in which Rₐ₁ and R_{b1} may be the same or different, and independently of each other hydrogen, a halogen, amino, alkyl, alkoxyalkyl, haloalkyl, aryl, or heterocycle, or Rₐ₁ and R_{b1} may be in the form of a heterocycle with a nitrogen atom attached thereto. Here, the number of Rₐ₁ and R_{b1} may be plural depending on the atom attached thereto, preferably alkyl may be C1-C6 alkyl, and aryl may be C6-C12 aryl, and heterocycle and heteroaryl may be C3-C12 heterocycle and heteroaryl.

Implementations relate to a method of forming a specific target pattern using photolithography in a process of manufacturing electronic devices such as semiconductor devices. Implementations also relate to a method of forming a resist pattern required to form a specific target pattern, and to a process including dry development when the resist pattern is formed. In addition, implementations relate to a resist rinse material used in a process of forming a resist pattern.

The resist pattern may be any pattern to be applied to a target layer, and may be, for example, a line-and-space pattern, a hole pattern, or the like, but implementations are not limited thereto. Hereinafter, ease of description, an example will be provided in which a resist pattern has a line-and-space pattern.

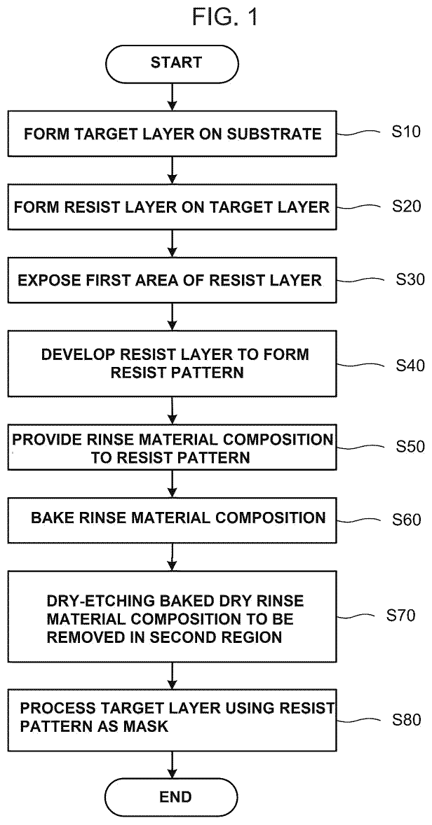

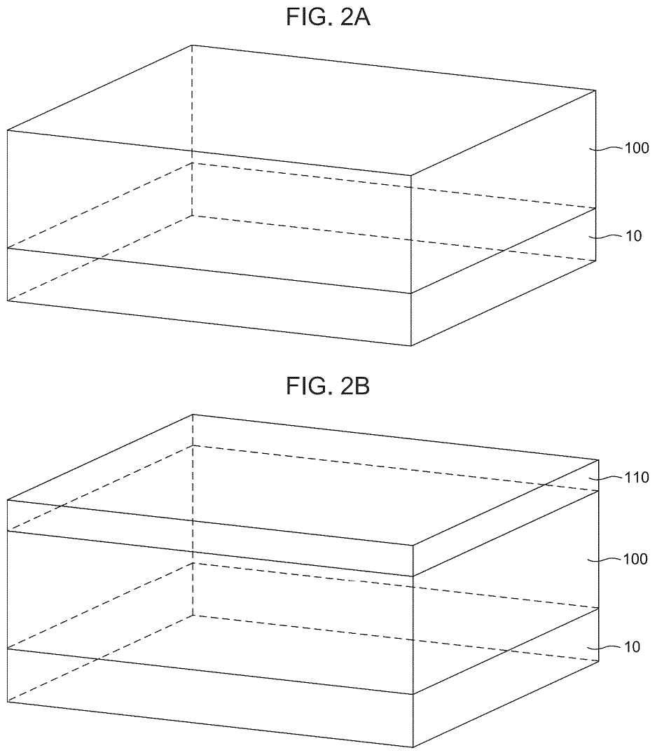

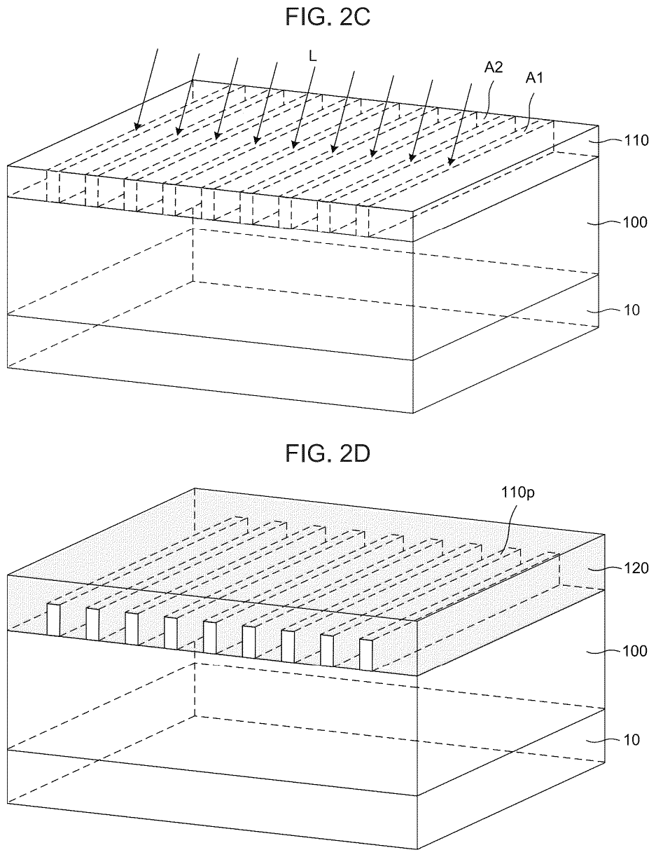

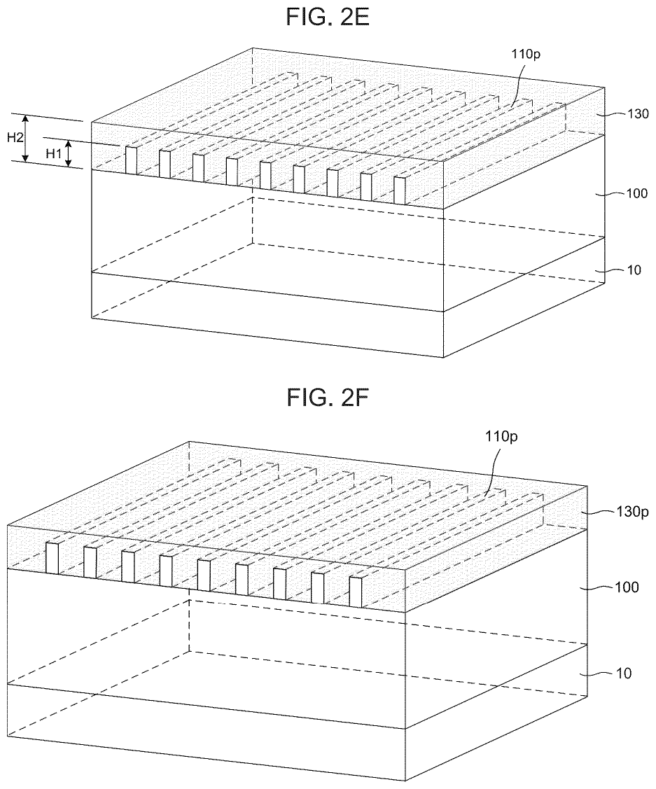

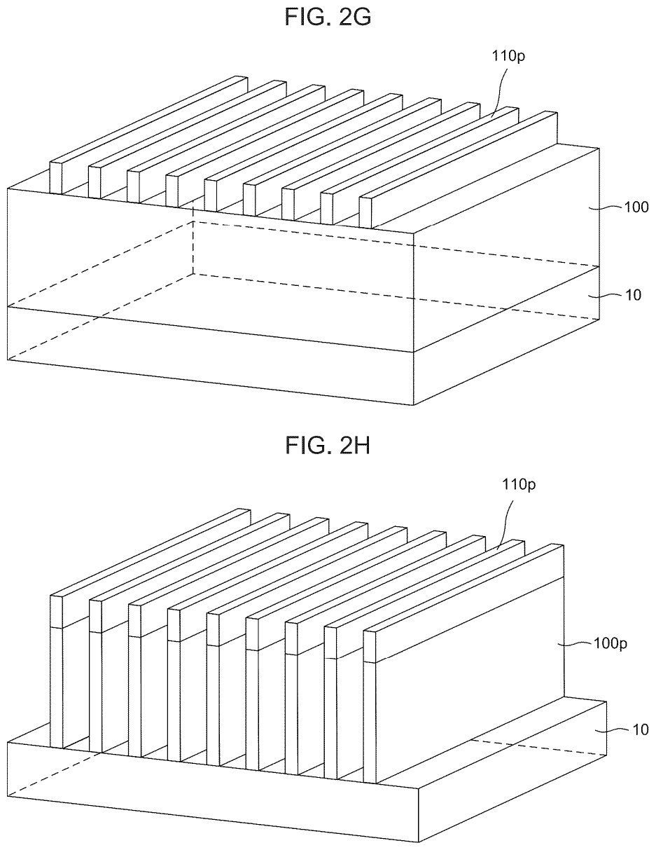

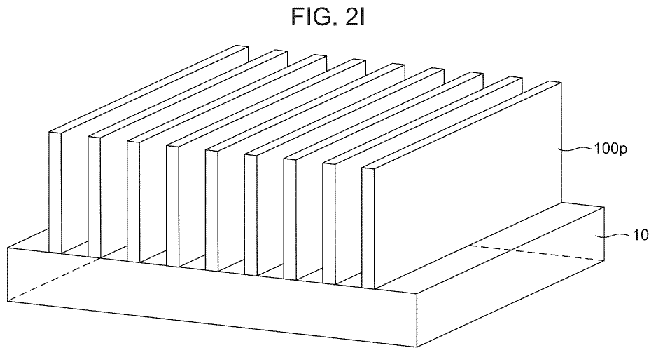

FIG. 1 is a flowchart illustrating a method of forming a target pattern 100p having a specific shape according to an implementation, and FIGS. 2A to 2I are cross-sectional views illustrating the method of forming the target pattern 100p based on the order of the flowchart illustrated in FIG. 1.

Referring to FIG. 1 and FIGS. 2A to 2I, the target pattern 100p may be formed by forming a target layer 100 on a substrate 10 (S10), forming a resist layer 110 on the target layer 100 (S20), exposing a first area of the resist layer 110 (S30), developing the resist layer 110 to form a resist pattern 110p (S40), applying a rinse material composition 130 to the resist pattern 110p (S50), baking the rinse material composition 130 (S60), removing a baked dry rinse material composition 130p in a second region by dry etching (S70), and processing the target layer 100 using the resist pattern 110p as a mask (S80).

Referring to FIG. 2A, a target layer 100 for a predetermined target pattern to be formed may be formed on a substrate 10.

The target pattern refers to features constituting an electronic device, for example, integrated circuits or another semiconductor device and having a specific pattern, for example, a topography. The target layer 100 may correspond to a layer for forming such features, and the target pattern may be obtained by patterning the target layer 100 in a specific manner.

The substrate 10 may be a substrate having a surface on which the target pattern is formed, and various substrates may be used as the substrate 10. For example, the substrate 10 may be a semiconductor substrate. The semiconductor substrate may include a semiconductor such as silicon (Si) or germanium (Ge), or a compound semiconductor such as SiGe, SiC, GaAs, InAs, or InP. In an implementation, the semiconductor substrate may include at least one of a group III-V material and a group IV material. The group III-V material may be a binary, ternary, or quaternary compound containing at least one III group atom and at least one V group atom. The group III-V material may be a compound containing at least one atom of indium (In), gallium (Ga), and aluminum (Al) as the group III atom and at least one atom of arsenic (As), phosphorus (P), and antimony (Sb) as the group V atom. For example, the group III-V material may be selected from InP, InzGa_{1-z}As (0≤z≤1), or AlzGa_{1-z}As (0≤z≤1). The binary compound may be, for example, one of InP, GaAs, InAs, InSb, or GaSb. The ternary compound may be one of InGaP, InGaAs, AlInAs, InGaSb, GaAsSb, or GaAsP. The group IV material may be Si or Ge. However, the group III-V material and the group IV materials, which are able to be used in electronic devices such as integrated circuit devices according to implementations, are not limited to above-mentioned examples. For example, the semiconductor substrate may have a silicon-on-insulator (SOI) structure. The semiconductor substrate may include a conductive region, for example, a doped well or a doped structure. However, the substrate is not limited to a semiconductor substrate, and may be a substrate formed of glass, quartz, metal, polymer resin, or the like, as necessary.

The target layer 100 may be an insulating layer, a conductive layer, or a semiconductor layer. For example, the target layer 100 may be formed of metal, alloy, metal carbide, metal nitride, metal oxycarbide, metal oxysilicide, semiconductor, polysilicon, oxide, nitride, oxycarbide, or combinations thereof, but implementations are not limited thereto.

A functional layer may be formed on the target layer 100 before forming the resist layer 110 to be described later, as necessary. The functional layer may be a layer to prevent a resist composition for forming the resist layer 110 from being affected by a lower target layer 100. In an implementation, the functional layer may be formed of an organic or inorganic anti-reflective coating (ARC) material for a KrF excimer laser, an ArF excimer laser, an extreme ultraviolet (EUV) laser, or any other light sources. In an implementation, the functional layer may be made of a bottom anti-reflective coating (BARC) film or a developable bottom anti-reflective coating (DBARC) film. In an implementation, the functional layer may include an organic component having an absorbing structure. The absorbing structure may be, for example, a hydrocarbon compound having one or more benzene rings or a fused structure of benzene rings. The functional layer may be formed to have a thickness of about 1 nm to about 100 nm, but implementations are not limited thereto. In an implementation, the functional layer may be omitted.

Referring to FIG. 2B, a resist layer 110 may be formed on the target layer 100.

The resist layer 110 may be formed of a photosensitive resist. The photo-sensitive resist may include a photosensitive metal and/or photosensitive crosslinkable molecules. In an implementation, the light may be light within an ultraviolet region, for example, EUV light within an EUV region, and the photosensitive crosslinkable molecules may be compounds sensitive to EUV light.

In an implementation, an example of a photosensitive crosslinkable molecule may be an organometallic oxide.

In an implementation, the resist layer 110 may include a crosslinkable molecule of Chemical Formula 1.

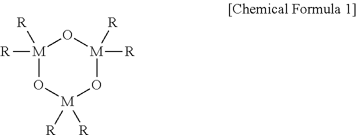

where M may be at least one element selected from the group consisting of tin (Sn), zinc (Zn), indium (In), titanium (Ti), strontium (Sr), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), or manganese (Mn).

Each R bonded to M may be independently an alkyl group of 1 to 30 carbon atoms. In an implementation, alkyl groups bonded to Sn may be the same or different. In an implementation, R may each independently be selected from the group consisting of ethyl, i-propyl, n-propyl, t-butyl, i-butyl, n-butyl, sec-butyl, n-pentyl, i-pentyl, t-pentyl, sec-pentyl, or mixtures thereof.

Crosslinkable molecules of the above Chemical Formula 1 may form a macromolecule by forming a covalent bond, for example, an M—O—M bond, to another crosslinkable molecule through exposure to irradiated light of, for example, a specific wavelength or to an electron beam (e-beam).

In an implementation, a metal of the crosslinkable molecule of Chemical Formula 1 may be tin, so that the crosslinkable molecule may be represented by Chemical Formula 2.

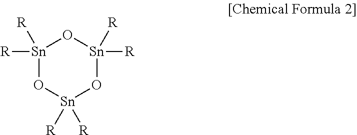

In an example, a crosslinkable molecule having the structure of Chemical Formula 2 may be crosslinked in the form of Sn—O—Sn or Sn—Sn bonds by exposure, and a relatively strong crosslinked bond may then be obtained to prevent pattern collapse of a resist pattern when being processed as the resist pattern. In addition, the crosslinkable molecule may have improved etching resistance due to a metal contained in the crosslinkable molecule.

In an implementation, the resist layer 110 may include, for example, a crosslinkable molecule of Chemical Formula 3 and/or Chemical Formula 4 and/or other organometallic materials.

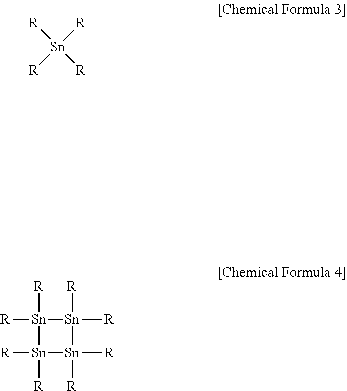

In these example, each R bonded to tin in Chemical Formula 3 or 4 may independently include an alkyl group of 1 to 50 carbon atoms. In an implementation, the alkyl groups bonded to Sn may be the same or different from each other.

In the above Chemical Formulas 1 to 4, the alkyl group R bonded to the metal M (e.g., tin) may be a substituted or unsubstituted alkyl group. For example, the alkyl group may be partially substituted with fluorine for hydrogen and may have a formula of CₙFₓH₂ₙ₊₁. In an implementation, in addition to the alkyl groups bonded to the metal M, other ligands may also be coordinated to the metal. The ligands may be any moiety substituted to form an M-OH moiety, such as a moiety selected from the group consisting of amines (for example, dialkylamino and monoalkylamino), alkoxy, carboxylates, halogens, or mixtures thereof.

In an implementation, the resist layer 110 may be formed to have a thickness of 5 nm to 100 nm, 8 nm to 50 nm, or 5 nm to 20 nm.

The resist layer 110 may be formed on the substrate 10 by wet deposition (for example, coating) or dry deposition (for example, chemical vapor deposition (CVD) or atomic layer deposition (ALD)). The coating may be performed by a method such as spin coating, spray coating, or dip coating.

In an implementation, the resist layer 110 may be formed by coating a resist composition and then thermally treating the resist composition.

As the process of thermally treating the resist composition, a first baking process (a soft baking process) may be performed. The first baking process may be performed to remove a portion of solvent inside the resist layer 110 and to stably fix the resist layer 110 onto the target layer 100.

The first baking process may be performed at a temperature of about 60° C. to about 300° C. for about 10 seconds to about 300 seconds. However, implementations are not limited thereto, and the first baking process may be performed at a different temperature and time or may be omitted. For example, the soft baking process may be performed at a temperature of about 70° C. to about 250° C. for about 20 seconds to about 200 seconds, or at a temperature of about 80° C. to about 160° C. for about 30 seconds to about 150 seconds. Alternatively, the first baking process may be performed within a range between any two of the above-mentioned numerical values.

The resist layer 110 may be formed to have a thickness of about 8 nm to about 1 μm but is not limited thereto. For example, the resist layer 110 may be formed to have a thickness of 10 nm to 100 nm, or 10 nm to 50 nm. When the thickness of the resist layer 110 is significantly larger beyond the above range, a subsequently formed resist pattern may collapse. When the thickness of the resist layer 110 is significantly smaller than the above range, the resist pattern may be broken.

Referring to FIG. 2C, an exposure process may be performed to apply light to a specific region of the resist layer 110.

The resist layer 110 includes a region in which light is applied (hereinafter referred to as a “first area A1”) and a region in which light is not applied (hereinafter referred to as a “second region A2”). Light of a specific wavelength, causing reaction of molecules in the resist layer 110, may be applied to only the first area A1. In this case, the light provided to the first area A1 may be EUV. The light provided to the first area A1 may be selected as crosslinking photosensitive crosslinkable molecules in the resist layer 110. The crosslinkable molecules in the above Chemical Formulas 1 to 4 may be exposed to the light to be crosslinked in the form of M—O—M bonds or M—M bonds, such as Sn—O—Sn bond or Sn—Sn bond. In an implementation, the light may have a wavelength of, for example, 248 nm, 193 nm, 157 nm, or 13.5 nm.

Accordingly, the above crosslinkable molecules in the exposed first area A1 are bonded to each other to form a macromolecule, and the crosslinkable molecules in the unexposed second region A2 are not bonded to each other. This may result in a difference in solubility between a crosslinked macromolecule and uncrosslinked crosslinkable molecules.

In an implementation, the resist layer 110 may include a photoacid generator (PAG).

In an implementation, although not illustrated in the drawing, an exposure mask having a plurality of light shielding areas and a plurality of light transmitting areas may be aligned at a predetermined location on the resist layer 110 to expose the first area A1 of the resist layer 110. The first area A1 of the resist layer 110 may be exposed through the plurality of light transmitting areas of the exposure mask. A KrF excimer laser 248 nm, an ArF excimer laser 193 nm, an F₂ excimer laser 157 nm, or an EUV laser 13.5 nm may be used to expose the first area A1 of the resist layer 110. In an implementation, a reflective photomask, rather than a transmissive photomask, may be used depending on the type of light source.

In the unexposed second area A2, the crosslinkable molecule does not form a macromolecule and remains in the state of a crosslinkable molecule, resulting in a difference in solubility of the first area A1 in a developer.

In an implementation, the resist layer 110 may be subjected to a second baking process after the first area A1 of the resist layer 110 is exposed. The second baking process may be performed to relieve the stress of the resist layer 110 and improve the adhesion to the lower target layer 100.

The second baking process may be referred to as a post-exposure baking process and may be performed at a temperature of about 50° C. to about 400° C. for about 10 seconds to about 300 seconds. However, implementations are not limited thereto, and the second backing process may be performed at different temperature and time, or it may be omitted. For example, the second baking process may be performed at a temperature of about 65° C. to about 300° C. for about 20 seconds to about 200 seconds, or at a temperature of about 80° C. to about 200° C. for about 30 seconds to about 150 seconds. Alternatively, the second baking process may be performed within a range between any two of the above-mentioned numerical values.

In an implementation, the degree of networking between crosslinkable molecules in the first area A1 may further increase during the second baking process on the resist layer 110. Accordingly, a difference in solubility between the exposed first area A1 and the unexposed second area A2 of the resist layer 110 in the developer 120 may be further increased, and pattern collapse may be prevented.

Referring to FIG. 2D, a developer 120 may be applied to the exposed resist layer, and the resist layer 110 of the first area A1 and the second area A2 may be developed. In this case, the resist layer 110 corresponding to the first area A1 is crosslinked, and may be maintained as it is, due to a low solubility thereof. In addition, the resist layer 110 of the second area A2 is not crosslinked and may be dissolved by the developer 120 to be removed. As a result, a first resist pattern 110p including the exposed first area A1 may be formed.

The developer 120 may be provided sufficiently to completely cover the resist layer 110. Accordingly, the developer 120 may be present on an upper side of the resist layer 110 with a thickness greater than a predetermined thickness.

Examples of the developer 120 may include n-butyl acetate, propylene glycol mono ethyl ether acetate, 2-heptanone, tetramethylammonium hydroxide, methyl acetate, ethyl acetate, isopropyl acetate, amyl acetate, isoamyl acetate, methoxy ethyl acetate, ethoxy ethyl acetate, propylene glycol mono methyl ether acetate, ethylene glycol mono ethyl ether acetate, ethylene glycol mono propyl ether acetate, ethylene glycol mono butyl ether acetate, ethylene glycol mono phenyl ether acetate, diethylene glycol mono methyl ether acetate, diethylene glycol mono propyl ether acetate, diethylene glycol mono ethyl ether acetate, diethylene glycol mono phenyl ether acetate, diethylene glycol mono butyl ether acetate, diethylene glycol mono ethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol mono methyl ether acetate, propylene glycol mono propyl ether acetate, 2-ethoxybutyl acetate, 4-ethoxybutyl acetate, 4-propoxybutyl acetate, 2-methoxy pentyl acetate, 3-methoxy pentyl acetate, 4-methoxy pentyl acetate, 2-methyl-3-methoxy pentyl acetate, 3-methyl-3-methoxy pentyl acetate, 3-methyl-4-methoxy pentyl acetate, 4-methyl-4-methoxy pentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, 2-hydroxypropyl methyl propionate, 2-hydroxypropyl ethyl propionate, methyl 3-methoxypropionate, ethyl 3-methoxypropionate, ethyl 3-ethoxypropionate, propyl 3-methoxypropionate, and the like. A surfactant, or the like, may be further included in the developer 120. A development reaction of the resist layer 110 by the developer 120 may be performed at a temperature of 1° C. to 80° C., 3° C. to 65° C., or 5° C. to 50° C., and may be performed for 1 second to 2000 seconds, 5 seconds to 1000 seconds, or 10 to 600 seconds.

In an implementation, the resist layer 110 is a positive-type layer, so that an unexposed portion is described as being removed. However, implementations are not limited thereto, and the resist layer 110 may be a negative-type layer, so that an exposed portion may be removed.

Referring to FIG. 2E, a rinse material composition 130 may be provided on the resist pattern 100p provided with the developer 120 on the target layer 100. The rinse material composition 130 may be provided to substitute the developer 120 with the rinse material composition 130. The rinse material composition 130 according to an implementation may be a composition including a dry development rinse material.

The rinse material composition 130 may be provided on the developer 120 by coating, or the like, push out the developer 120, and permeate into a position, at which the developer 120 was located, to completely substitute the developer 120.

A cleaning process using a rinse liquid may be performed before providing the rinse material composition 130 on the developer 120. The rinse liquid may be the same as the above-described developer 120, or the rinse liquid may be different from the above-described developer 120. The rinse liquid, different from the above-described developer 120, may include a different solvent or deionized (DI) water in addition to the above-described developer 120. For example, the rinse liquid according to an implementation may be a solution including methyl isobutyl carbinol, isopropyl alcohol, propylene glycol mono ethyl ether acetate, organic solvent, and/or DI water.

The rinse material composition 130 may be provided to completely cover the developed resist layer 110 and may have a predetermined thickness in a direction upward from a surface of the resist layer 110. For example, the rinse material composition 130 may be applied to an extent that completely covers the resist pattern 110p after development. For example, when a height of the resist pattern 110p is referred to as a first height H1 and a height at which the rinse material composition 130 is formed is referred to as a second height H2 (both H1 and H2 are defined with respect to an upper surface of the target layer 100), the height H2 has a larger value than the first height H1. For example, the second height H2 may have a value 1% to 300% greater than the first height H1.

However, the height at which the rinse material composition 130 is formed is not limited thereto. In an implementation, the second height H2 may have a smaller value than the first height H1. For example, the second height H2 may have a value of 5% to 100% of the first height H1.

In this process, the developer 120 may be removed and the rinse material composition 130 may be formed on the target layer 100 to clean the resist pattern 110p with the rinse material composition 130 and simultaneously fill a groove that may be present in the resist pattern 110p. To this end, the rinse material composition 130 may be selected as including a material having a functional group that may be bonded to an uneven portion of the developed resist pattern 110p.

The rinse material composition 130 may include a dry development rinse material (DDRM) compound and a residual solvent that may form hydrogen bonds, van der Waals bonds, coordination bonds, or ionic bonds with the crosslinked photosensitive crosslinkable molecules. The DDRM compound may strongly interact with the photosensitive crosslinkable molecules in the rinse material composition 130 and may be a compound acting as a Lewis base or a compound forming hydrogen bonds.

In an implementation, DDRM molecules constituting the DDRM compound may include a substituted or unsubstituted chain or cyclic carbon compound body, having a carbon number of 4 to 100, and at least one hydrophilic group B attached to the body and forming hydrogen bonds, van der Waals bonds, coordination bonds, or ionic bonds with the photosensitive crosslinkable molecules.

The rinse material composition 130 may further include a surfactant and/or a polymeric adsorbent. The rinse material composition 130 according to an implementation will be described later.

Referring to FIG. 2F, the rinse material composition 130 may be dried and/or subjected to a third baking process. The third baking process may also be referred to as a post-rinse baking process or a hard baking process. The rinse material composition 130 may be dried by various methods such as spin drying. The rinse material composition 130 may be subjected to the third baking process at a temperature of about 50° C. to about 400° C. for about 10 seconds to about 300 seconds, but implementations are not limited thereto. According to an implementation, the third baking process may be performed at different temperatures and times. For example, the third baking process may be performed at a temperature of about 65° C. to about 300° C. for about 20 seconds to about 200 seconds, or at a temperature of about 80° C. to about 200° C. for about 30 seconds to about 150 seconds. Alternatively, the third baking process may be performed within a range between any two of the above-mentioned numerical values.

In this case, the solvent in the rinse material composition 130 may be removed, and only a solid content in the rinse material composition remains in the baked rinse material composition 130p.

Referring to FIG. 2G, the baked rinse material composition 130p may be removed by dry etching. In this case, only the baked rinse material composition 130p of the second area A2 (see FIG. 2C) may be removed and the resist pattern 110p of the first area A1 (see FIG. 2C) may not be removed. As a result, the resist pattern 110p may remain on the target layer 100.

Dry etching for removal of the baked rinse material composition 130p may be a plasma treatment. The plasma treatment may be performed by generating plasma of a specific process gas while supplying the specific process gas and then applying the plasma of the process gas to the baked rinse material composition 130p. The process gas in the plasma treatment according to an implementation may be an oxygen-based gas, for example, O₂. In an implementation, for example, O₂ reactive ion etching (RIE) may be used for the plasma treatment.

In an implementation, the process gas may further include an inert gas such as helium (He), neon (Ne), or argon (Ar) in addition to the oxygen-based gas.

A flow rate of the process gas for the plasma treatment may be, for example, about 20 sccm to about 250 sccm. In an implementation, the flow rate of the process gas may be about 20 sccm to about 250 sccm, about 30 sccm to about 230 sccm, about 40 sccm to about 200 sccm, about 50 sccm to about 180 sccm, about 60 sccm to about 160 sccm, about 70 sccm to about 140 sccm, about 80 sccm to about 120 sccm, or a range between any two of the above-mentioned numerical values.

A pressure of a chamber for the plasma treatment may be, for example, about 0.5 mTorr (0.0667 Pa) to about 100 mTorr (13.33 Pa). In an implementation, the pressure of the chamber may be about 0.5 mTorr to about 100 mTorr, about 1 mTorr to about 80 mTorr, about 1.5 mTorr to about 50 mTorr, about 2 mTorr to about 30 mTorr, about 2.5 mTorr to about 20 mTorr, about 3 mTorr to about 15 mTorr, about 3.5 mTorr to about 10 mTorr, about 4 mTorr to about 8 mTorr, or a range between any two of the above-mentioned numerical values.

The plasma treatment may be performed for about 1 second to about 10 minutes, or 1 second to 8 minutes, or 1 second to 5 minutes under the above conditions. Alternatively, the plasma treatment may be performed within a range between any two of the above-mentioned numerical values.

In an implementation, an etch-back process using a fluorine-containing gas may be omitted for the removal of the baked rinse material composition 130p.

According to the related art, removal of a baked rinse material composition was performed by two processes including a first process and a second process. The first process was an etch-back process performed to etch the baked rinse material composition on an upper side of a resist pattern until an upper surface of the resist pattern was exposed. The second process was an etching process performed to further dry etch the remaining resist pattern and the baked rinse material composition using an oxygen-containing process gas. When the remaining resist pattern is etched among the remaining resist pattern and the baked rinse material composition, the rinse material portion remains as a final pattern. This is because the related art uses a silicon-containing polymer material having high etching resistance as the DDRM compound, so that the upper surface of the resist pattern is exposed and a resist pattern that is relatively easy to be etched is etched instead of the silicon polymer material having high etching resistance. Accordingly, the final pattern corresponding to an unexposed portion (a second area A2), rather than the exposed portion (a first area A1), is formed to cause tone reversal.

As described above, the related art should perform two process including an etch-back process of etching the baked rinse material composition on the resist pattern and an etching process of etching the resist pattern without etching the baked rinse material composition, and thus process gases were differently selected. For example, the etch-back process is performed using a fluorine-containing gas. The used fluorine-containing gas was a C1 to C3 fluoroalkane containing at least one hydrogen atom, a mixed gas of hydrogen (H₂) and a fluorinated compound, a mixed gas of a C1 to C3 fluoroalkane containing at least one hydrogen atom and a fluorinated compound, a mixture of hydrogen (H₂) and C1 to C3 fluoroalkanes, or a mixture of C1 to C3 fluoroalkanes, hydrogen (H₂), and a fluorinated compound.

However, in an implementation, the baked rinse material composition 130p portion except for the resist pattern 110p corresponding to an exposed portion (the first area A1) may be removed in a single process, so that the exposed portion (the first area A1) remains as a final resist pattern 110p. Since the rinse material composition according to an implementation uses molecules having a lower etching resistance than a silicon-based DDRM material according to the related arts, the resist pattern 110p may be formed in the first area A1 without tone reversal by etching in a single process.

For example, there is no need to perform two processes including an etch-back process performed until the upper surface of the resist pattern 110p is exposed and an etching process performed to etch the baked dry rinse material formed of a material, different from that of the resist pattern 110p. Instead, a dry rinse material may be etched at a time in the single process. Accordingly, a process gas such as a fluorine-containing gas does not need to be used.

Referring to FIG. 2H, the target layer 100 may be processed using the resist pattern 110p as a mask to form a target pattern 100p.

The target layer 100 may be processed by various processes. Examples of the process of processing the target layer 100 may include a process of etching the target layer 100 exposed through an opening of the resist pattern 110p, a process of doping the target layer 100 with impurity ions, a process of forming an additional layer on the target layer 100 through the opening, or a process of modifying a portion of the target layer 100 through the opening. FIG. 2H illustrates an example of a process of processing the target layer 100 and illustrates a case in which the target pattern 100p is formed by etching the target layer 100 exposed through the opening.

In an implementation, the process of forming the target layer 100 may be omitted, and the resist pattern 110p itself may be processed into a specific structure.

Referring to FIG. 2I, the resist pattern 110p remaining on the target pattern 100p may be removed. An ashing process and a stripping process may be used to remove the resist pattern 110p.

In an implementation, the process of removing the resist pattern 110p may be optional, and the resist pattern 110p may not be removed.

The method of forming a pattern according to the above-described implementation may use a rinse material composition. The rinse material composition according to an implementation is intended to clean the resist layer and may include a DDRM compound and a solvent in which the DDRM compound is dissolved.

At least a portion of DDRM compound may form chemical bonds with materials constituting the resist pattern. For example, the DDRM compound may form predetermined chemical bonds with photosensitive crosslinkable molecules constituting the resist pattern, especially photosensitive crosslinkable molecules that have been polymerized by exposure. For example, the DDRM compound may be linked to photosensitive crosslinkable molecules via hydrogen bonds, van der Waals bonds, coordination bonds, or ionic bonds with the resist pattern and photosensitive crosslinkable molecules on a surface of the resist pattern.

The solvent may be any solvent capable of dissolving DDRM molecules. Examples of the solvent may include aromatic compounds (for example, xylene or toluene), alcohols (for example, 4-methyl-2-pentanol, 4-methyl-2-propanol, 1-butanol, methanol, isopropyl alcohol, or 1-propanol), ethers (for example, anisole or tetrahydrofuran), ester compounds (for example, n-butyl acetate, propylene glycol monomethyl ether acetate, ethyl acetate, or ethyl lactate), ketones (for example, methyl ethyl ketone, or 2-heptanone), or combinations thereof. However, implementations are not limited thereto. Since the DDRM molecules have hydrophilic groups B, the solvent may include at least a portion of polar solvents to sufficiently dissolve the DDRM molecules. The polar solvent may be used after being mixed with a non-polar solvent. In this case, the polar solvent may be provided in an amount of 50 wt % or more, for example, 60 wt % or more or 70 wt % or more, when a total amount of the solvent is 100 wt %.

A DDRM compound may include a plurality of DDRM molecules that is capable of bonding to the resist pattern and have a group, resistant to a subsequent etching process. Even when the DDRM compound is resistant to a subsequent etching process, the DDRM compound may have a lower etching resistance than an etching resistance of the resist pattern.

In an implementation, the DDRM molecules may include a body A, resistant to etching during a process of forming a resist pattern, and a hydrophilic group B, capable of chemically bonded to photosensitive crosslinkable molecules, as illustrated in Chemical Formula 5.

The body A may be a carbon compound having a hydrophobic property and low reactivity compared to an end portion, and the hydrophilic group B may be bonded to an end portion of the body A or the inside of the body portion A by a covalent bond. The body A may include at least one hydrophilic group B forming hydrogen bonds, van der Waals bonds, coordination bonds, or ionic bonds with crosslinked photosensitive crosslinkable molecules.

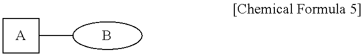

The body A may include a substituted or unsubstituted linear or cyclic hydrocarbon group having 4 to 100 carbon atoms. The body A may have a hydrocarbon group, having lower reactivity than a hydrophilic group B, as a basic component. Therefore, the body A may have a high etching resistance.

When the body A includes a linear carbon compound, the linear or cyclic carbon compound of the body A may also contain at least one carbonyl group and/or ether group therein. The body A may variously change in carbon atom, branch, and cyclic functional group to have sufficient etching resistance during a subsequent process of forming a resist pattern. In addition to hydrogen atoms of a substituted portion being replaced with a substituent, the body A may be provided as a chain or cyclic hydrocarbon and carbon of a main chain or a main ring may also be replaced with a heteroatom.

The hydrophilic group B may be an electron-rich functional group, capable of reacting with surfaces of crosslinked photosensitive crosslinkable molecules. The hydrophilic group B may include a hydroxyl group, a carboxyl group, a thiol group, an amino group, an amide group, or the like. Examples of a compound having such a hydrophilic group may include alcohol, carboxylic acid, sulfonic acid, sulfuric acid, phosphonic acid, phosphinic acid, phosphinic acid anhydride, carboxylates, phosphonate, amine, or thiols. When the hydrophilic group B is provided at the end portion of the body A, it may be —OH, —SH, —SO₃H, —OSO₃H, —COOH, —OPO₃H₂, —PO₃H₂, —NH₂, —NRH, —NR₂, —CONH₂, —CONR₂, —CONRH, or the like. When the hydrophilic group B is provided inside the body A, it may be, for example, —O—, —SO₃—, —S—, —OSO₃—, —CO—, —COO—, —OPO₃—, —PO₃—, —PO₂H—, —NH—, —CONH—, —NR—, —CONR—, or the like, where R is a substituted or unsubstituted alkyl group of 1 to 5 carbon atoms.

Chemical Formula 6 illustrates examples of DDRM molecules each having a body A and a hydrophilic group B, and the examples represent salicylic acid, mandelic acid, and gallic acid, respectively.

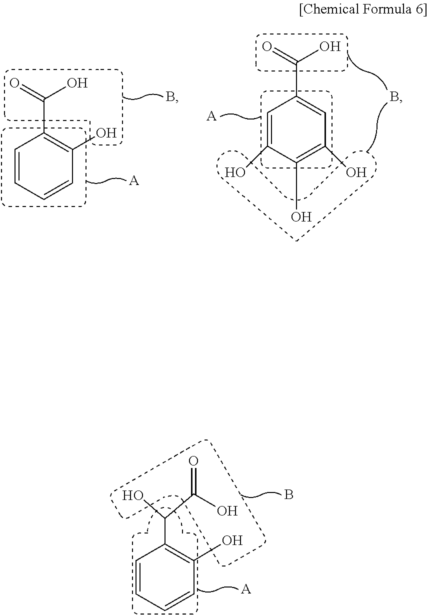

In an implementation, DDRM molecules may be a dendrimer-based compound that is a substituted or unsubstituted linear or cyclic carbon compound having a hydrophilic group at an end portion thereof.

The hydrophilic group of the dendrimer may include a hydroxyl group, a carboxyl group, a thiol group, an amino group, an amide group, or the like. For example, when the hydrophilic group is provided at an end portion of a body, it may be —OH, —SH, —SO₃H, —OSO₃H, —COOH, —OPO₃H₂, —PO₃H₂, —NH₂, —NRH, —NR₂, —CONH₂, —CONR₂, —CONRH, or the like. When the hydrophilic group is provided inside the body, it may be, for example, —O—, —SO₃—, —S—, —OSO3—, —CO—, —COO—, —OPO₃—, —PO₃—, —PO₂H—, —NH—, —CONH—, —NR—, —CONR—, or the like, where R is a substituted or unsubstituted alkyl group having 1 to 5 carbon atoms. In an implementation, the dendrimer-based compound may include a hydroxyl group or a carboxyl group as a functional group at an end portion thereof.

Chemical Formula 7 illustrates a dendrimer-based compound according to an implementation. The DDRM molecules according to an implementation may include at least one dendrimer-based compound, among dendrimer-based compounds of Chemical Formula 7.

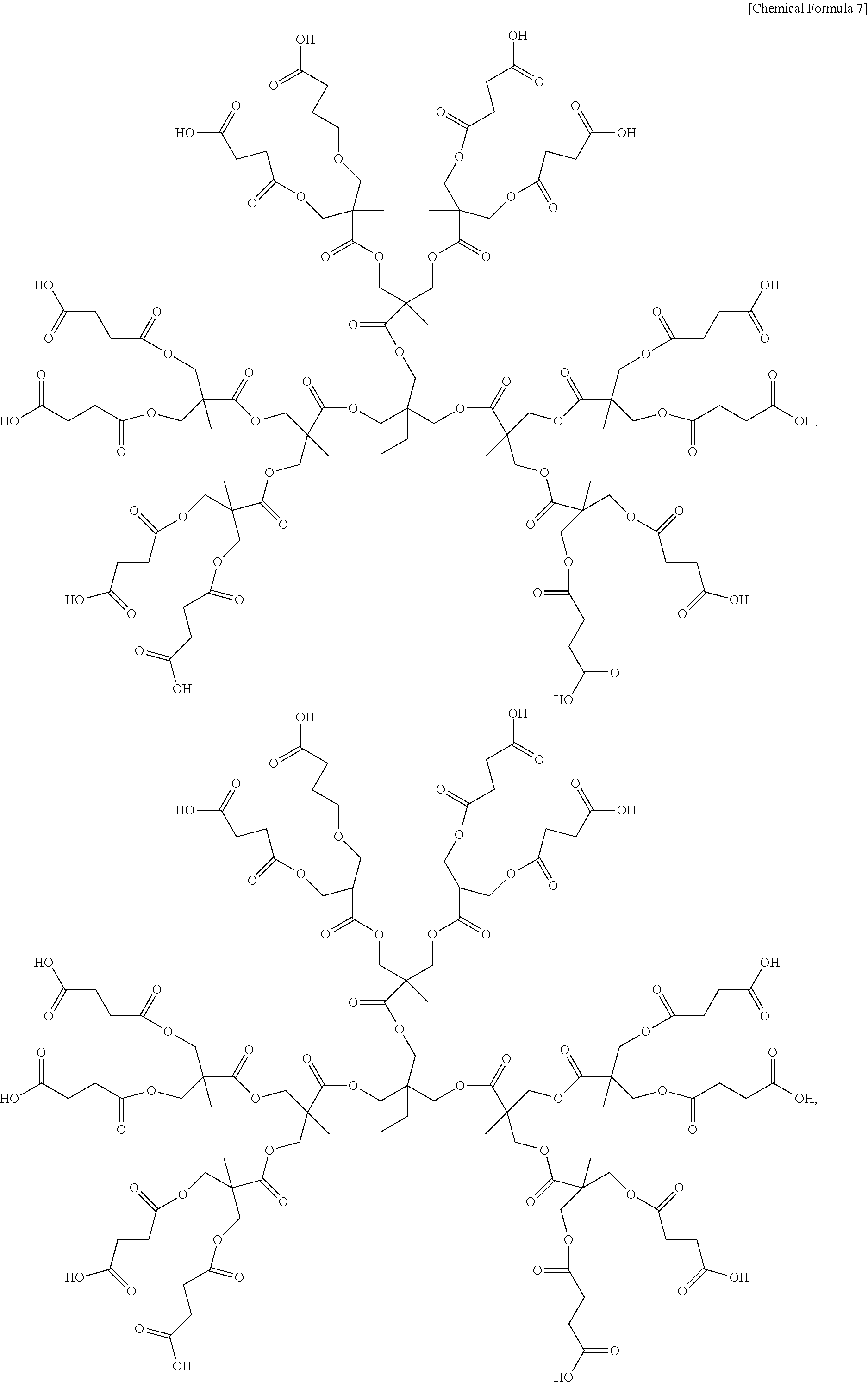

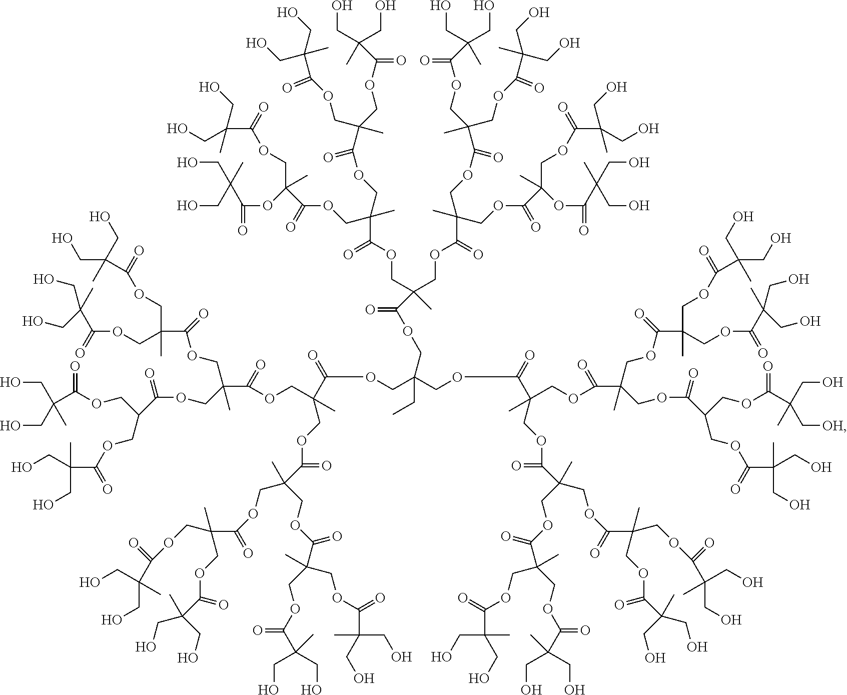

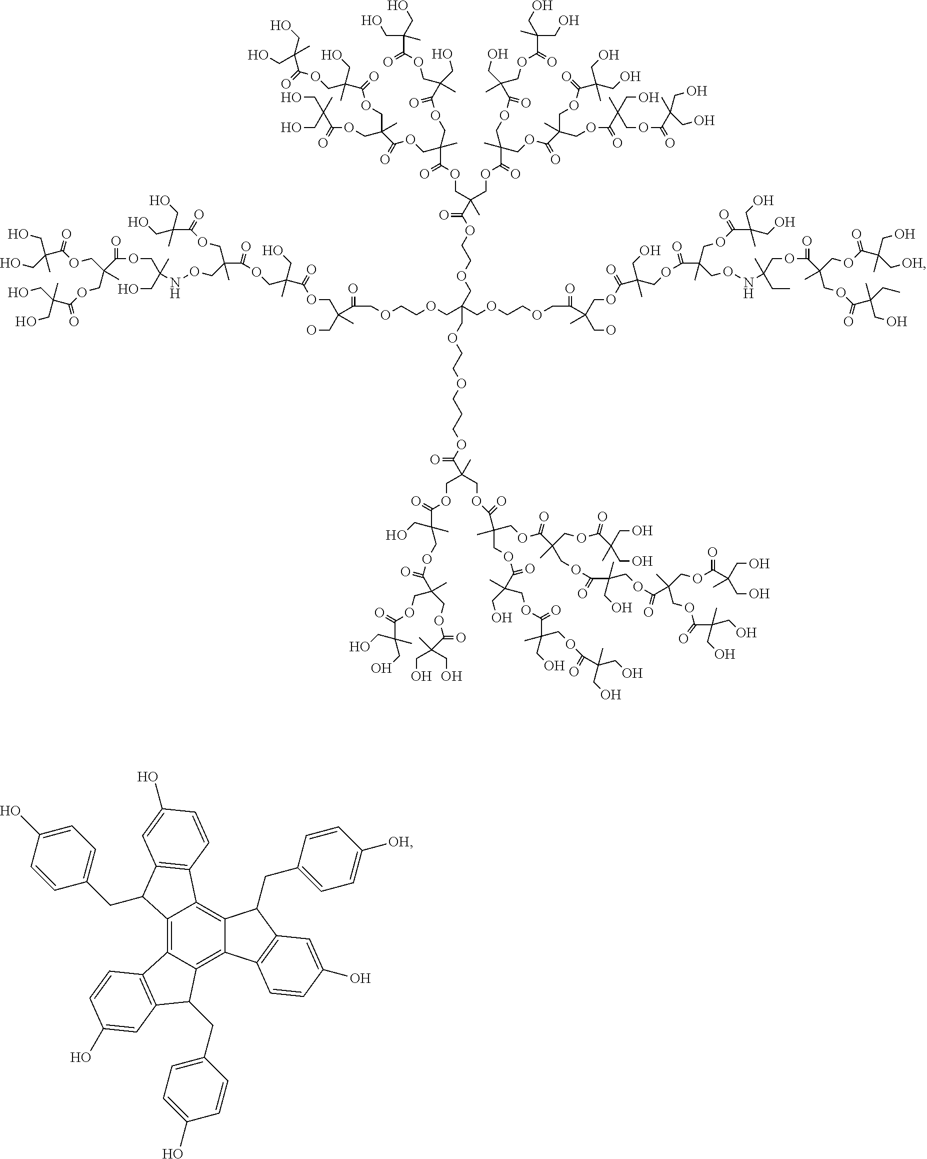

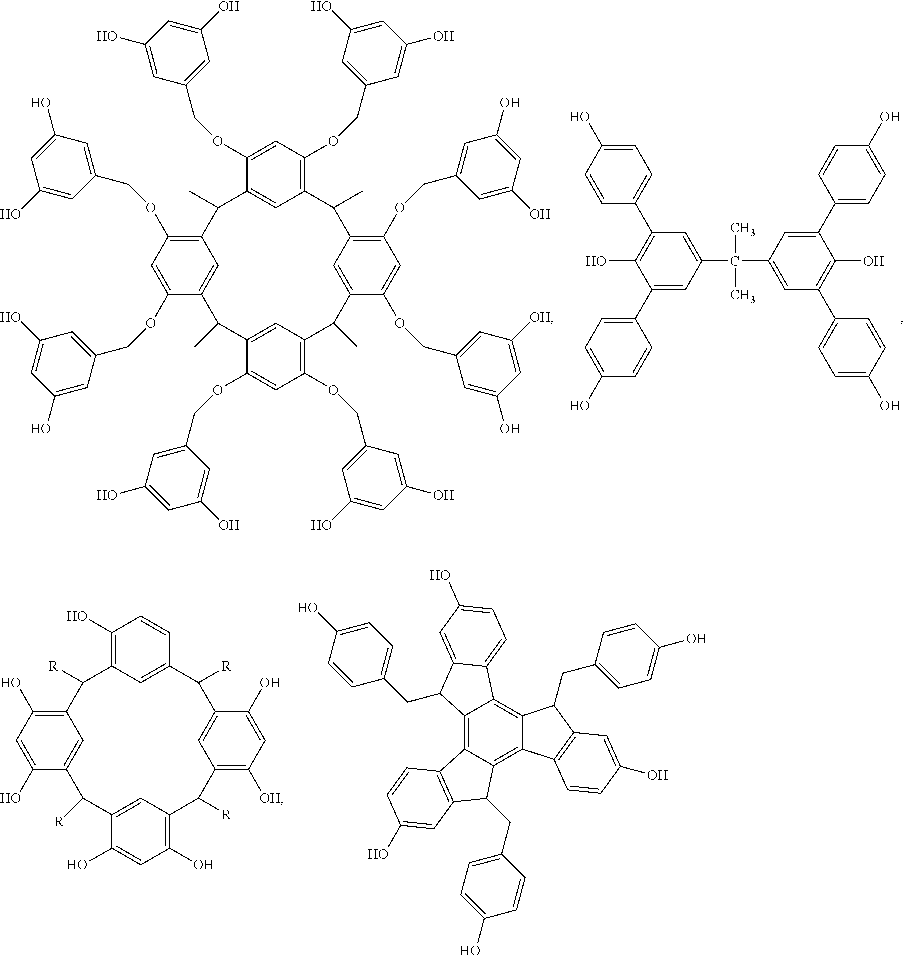

In Chemical Formula 7, R is —H or a linear or cyclic alkyl group of 1 to 6 carbon atoms. For example, R is —CH₃ or C₆H₁₃.

The DDRM molecules may be chemically bonded to grooves or valleys of polymerized photosensitive crosslinked polymers through the hydrophilic group B, and line width roughness (LWR) and line edge roughness (LER) may be improved through the chemical bonding of the DDRM molecules.

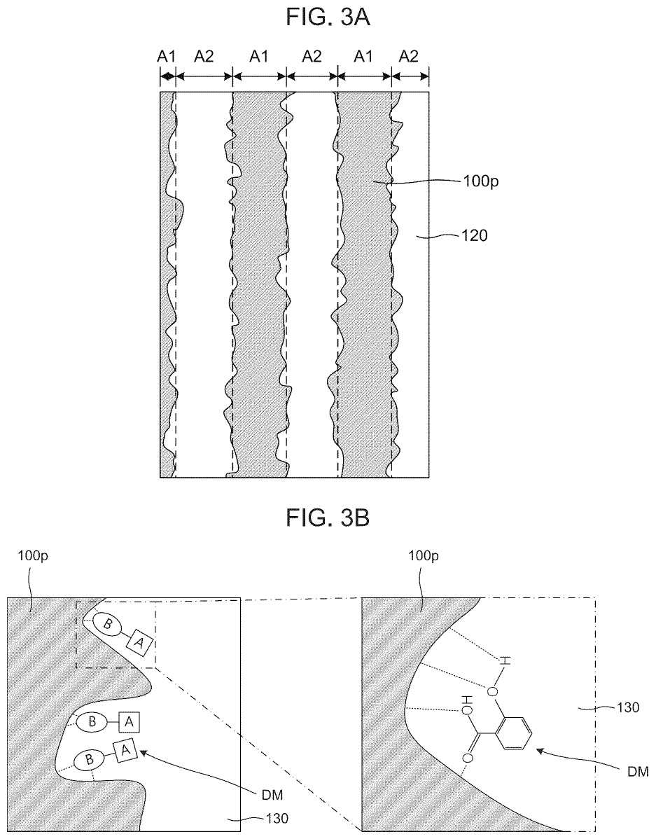

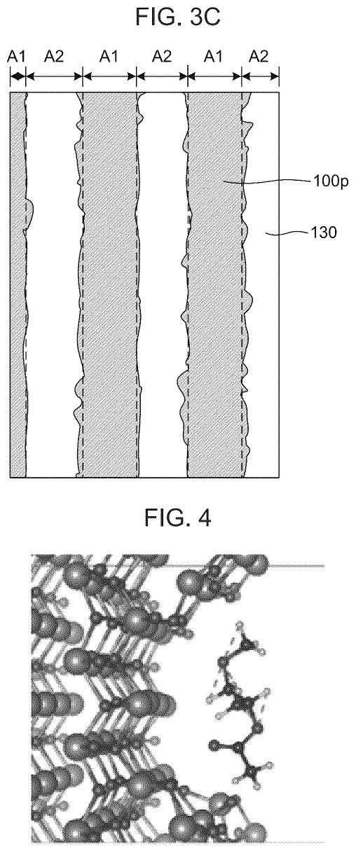

FIG. 3A is a diagram illustrating a profile of a resist pattern after development, FIG. 3B is a schematic diagram illustrating that DDRM molecules in a rinse material composition bond a resist pattern when the rinse material composition is applied to a resist pattern after development, and FIG. 3C is a diagram illustrating a profile of the resist pattern after the DDRM molecules bond with the resist pattern.

Referring to FIG. 3A, only the first area A1, other than the second area A2, may be exposed after the resist layer is formed. Accordingly, only the resist pattern 110p may be formed in the first area A1 during development. The resist pattern 110p developed after exposure may be different from the target pattern to be actually manufactured. As illustrated in FIG. 3A, the actually manufactured resist pattern 110p may have unevenness on a surface thereof depending on the degree of crosslinking at the time of exposure and the degree of contact with the developer 120. A difference between the target pattern to be manufactured and the actually manufactured resist pattern 110p may be quantified by line width roughness (LWR), line edge roughness (LER), or the like. In general, LWR may refer to the degree of irregularity of the overall linewidth, and LER may refer to the degree to which an edge of the actually manufactured pattern deviates from an edge of the target pattern.

Referring to FIG. 3B, DDRM molecules DM of the rinse material composition 130 according to an implementation may be bonded to a concave portion, for example, a groove or a valley, of the resist pattern 110p of the polymerized photosensitive crosslinked polymer through the hydrophilic group B. In FIG. 3B, the DDRM molecule DM is illustrated as being, for example, salicylic acid.

The DDRM according to an implementation may be bonded to a small groove or valley portion having a size of, for example, less than 2 nm to fill the groove or valley. The DDRM molecules DM may be bonded to both a concave portion and a convex portion of the resist pattern 110p, but the DDRM molecules DM bonded to the convex portion may be easily removed in a subsequent etching process.

As a result, roughness on the surface of the resist pattern may be reduced, as illustrated in FIG. 3C.

The above-described DDRM molecules DM may be bonded to the resist pattern in various forms. Chemical Formulas 8 and 9 conceptually illustrate an example of bonding of the DDRM molecules DM when a crosslinked metal oxide of the resist pattern is a tin oxide. Chemical Formulas 8 and 9, indicating a case in which the hydrophilic group B is a hydroxyl group, illustrates an example in which the hydrophilic group B forms hydrogen bonds with tin oxide.

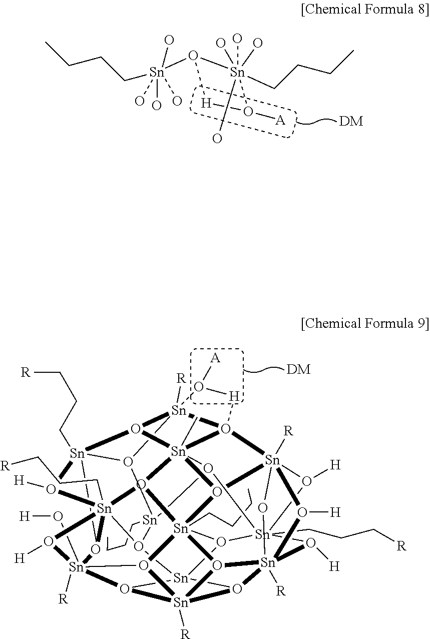

The above-described DDRM molecules according to an implementation form a stronger bond with the resist pattern than the solvent in the rinse material composition to fill the surface of the resist pattern and further protect the resist pattern more stably during an etching process.

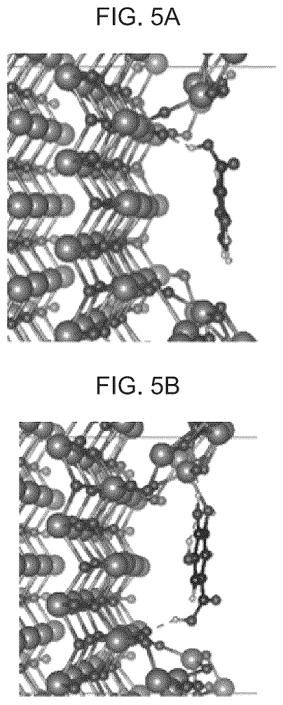

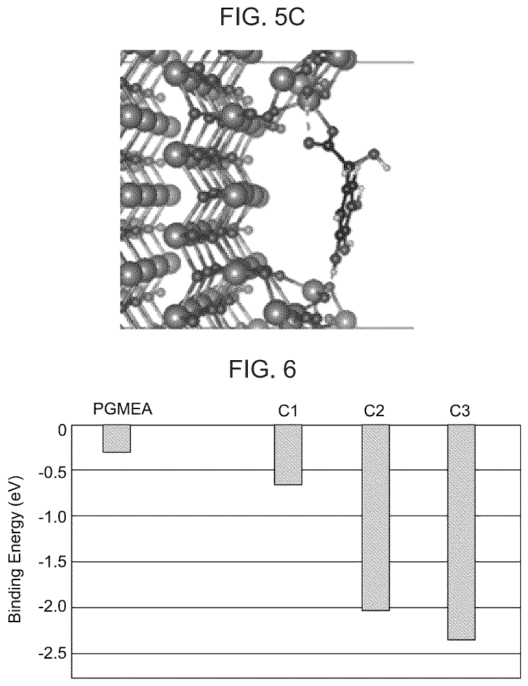

FIG. 4 is a diagram illustrating a simulation result of a bonding relationship between a solvent and the resist pattern when propylene glycol monomethyl ether acetate (P GMEA) is used as the solvent, and FIGS. 5A to 5C are diagrams illustrating simulation results of a bonding relationship between DDRM molecules and a resist pattern, respectively. FIG. 6 is a graph illustrating binding energy between the materials used in FIG. 4 and FIGS. 5A to 5C and the resist pattern. The resist pattern used in FIG. 4 and FIGS. 5A to 5C is a resist pattern containing a tin oxide, and the three compounds (first to third compounds) used in FIGS. 5A to 5C correspond to Chemical Formulas 10 to 12, respectively.

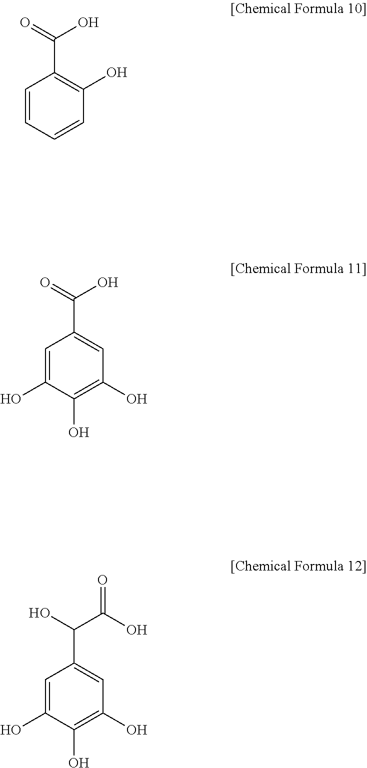 [SMILES: O=C(O)c1ccccc1O ; O=C(O)c1cc(O)c(O)c(O)c1 ; O=C(O)C(O)c1cc(O)c(O)c(O)c1]

From FIGS. 4, 5A to 5C, and 6, it can be seen that binding energy with the resist pattern is stronger than binding energy of the solvent when DDRM molecules are added. For example, in the above simulation, the PGMEA, a solvent, exhibited a binding energy of about −0.287 eV, but the first to third compounds exhibited binding energies of −0.641 eV, −2.045 eV, and −2.382 eV, respectively. From this, it can be seen that the more hydrophilic groups, the stronger the bonding force with the resist pattern. As described above, the DDRM molecules may be strongly bonded to the resist pattern. A solvent that is relatively weakly bonded may be easily removed during a drying process, but the DDRM molecules may remain in the resist pattern during drying and etching processes due to their strong bonding with the resist pattern.

As described above, the DDRM molecules may be bonded to the surface of the resist pattern at grooves or valleys of the resist pattern, and thus the grooves or valleys of the resist pattern may be filled with DDRM molecules. As illustrated in FIGS. 3A to 3C, roughness and irregularity of the surface of the resist pattern may be reduced. The reduction in the roughness and irregularity of the surface of the resist pattern refers to improvement of LWR and/or LER.

In fact, after development inspection (ADI) of the developed resist pattern, line edge roughness (LER) was found to be between 1.8 and 2.5 nm, and grooves and valleys of 2 nm or more were observed on the surface and sidewalls thereof. However, when a process is performed using a rinse material composition according to an implementation, LER may be implemented to be less than 2.0 nm, or less than 1.5 nm, or less than 1.2 nm.

In an implementation, the DDRM compound may be provided in an amount of 0.5 wt % to 10 wt %, 1 wt % to 5 wt %, or 1 wt % to 3 wt % with respect to the total amount of the rinse material composition, and the solvent may be provided as the remaining amount excluding the DDRM compound.

When the DDRM compound is less than the above range, it may be difficult to improve sufficient LWR and/or LER. When the DDRM compound is greater than the above range, additional time may be required to remove the DDRM compound during an etching process.

The rinse material composition according to an implementation may further include various functional additives. The additives may include a surfactant and/or a polymeric adsorbent.

When a surfactant is used as the additive, the surfactant may be a cationic surfactant, an anionic surfactant, or an amphoteric surfactant. A concentration of the surfactant in the rinse material composition may be about 1 ppm to about 50 ppm, about 5 ppm to 45 ppm, or about 10 ppm to 40 ppm. When the concentration of the surfactant in the rinse material composition is significantly low, a cleaning effect may be insufficient. When the concentration of the surfactant in the rinse material composition is high enough then it may be economically disadvantageous to use.

Examples of the cationic surfactant may include quaternary ammonium compounds such as alkyl trimethyl ammonium chloride, alkyltrimethyl ammonium bromide, alkyl trimethyl fluoride, dialkyl dimethyl ammonium chloride, hydrogenated tallow alkyl trimethyl ammonium chloride, and ditallow alkyl dimethyl ammonium chloride; and tertiary amidoamines such as cocaamidopropyl dimethylamine, stearamidopropyl dimethylamine, behenylamidopropyl dimethylamine, oleamidopropyl dimethylamine, and isostearamidopropyl dimethylamine. For example, the cationic surfactant may be cetyltrimethylammonium bromide (CTAB), tetramethylammonium chloride, stearyltrimethylammonium chloride, distearyldimethylammonium chloride, or dicetyldimethylammonium chloride.

Examples of the anionic surfactant may include alginate polymers, sodium dodecyl sulfate, linear alkylbenzene sulfonate, alpha-olefin sulfonate, alkyl sulfate esters, polyoxyethylene alkyl ester sulfates, alpha-sulfo fatty acid esters, alkyl benzene sulfonates, alkyl sulfates, alkyl ether sulfates, alpha-olefin sulfonates, alkanesulfonates, hydroxyalkanesulfonates, fatty acid monoglyceride sulfates, alkyl glycerol ether sulfates, alkali metal salts, alkaline earth metal salts, acyl glutamates, acyl taurates, acyl isethionates (SCI), sodium lauryl sulfate (SLS), sodium lauryl ether sulfate (SLES), linear alkylbenzene sulfonate (LAS), or monoalkyl phosphate (MAP).

Examples of the amphoteric surfactant may include alkyl amidopropyl betaine, alkyl dimethyl betaine, alkyl amphoacetate, or alkyl amphodiacetate.

The cationic surfactants, anionic surfactants, and amphoteric surfactants described above are all exemplary, and implementations are not limited thereto.

When a polymeric adsorbent is used as the additive, the polymeric adsorbent may be an acrylic polymer crosslinked with an acrylic monomer. The polymer adsorbent may be adsorbed on the surface of the resist pattern by van der Waals bonding, or the like, and may play an additional role of filling the recessed portions, for example, grooves or valleys, of the resist pattern of the polymerized photosensitive crosslinked polymer.

For example, the acrylic polymer may be a polymer crosslinked with monomers such as methyl methacrylate, ethylene glycol dimethacrylate, diethylene glycol dimethacrylate, triethylene glycol dimethacrylate, propylene glycol dimethacrylate, neopentyl glycol dimethacrylate, 1,4-butanediol dimethacrylate, 1,6-hexanediol dimethacrylate, bisphenol A dimethacrylate, pentaerythritol dimethacrylate, pentaerythritol trimethacrylate, pentaerythritol tetramethacrylate, pentaerythritol hexamethacrylate, dipentaerythritol dimethacrylate, dipentaerythritol trimethacrylate, dipentaerythritol dipentaerythritol hexamethacrylate, bisphenol epoxymethacrylate, ethylene glycol monomethyl ether methacrylate, trimethylolpropane trimethacrylate, tris(meth)acryloyloxyethyl phosphate, novolac epoxymethacrylate, or combinations thereof, but implementations are not limited thereto. In an implementation, the polymeric adsorbent used as the additive may be polymethyl methacrylate (PMMA) crosslinked with methyl methacrylate.

Polymeric adsorbents, similar to DDRM molecules, are solids in the rinse material composition and have a similar function in terms of improving a surface of the crosslinked resist pattern having uneven portions.

Therefore, in an implementation, the DDRM molecules may be omitted and the polymeric adsorbent may be used instead of the DDRM molecules.

When an additive such as a surfactant and/or a polymeric adsorbent is included in the rinse material composition, the DDRM molecules and the additive may constitute a solid, except for solvent, in the rinse material composition. The DDRM molecules may be contained in an amount of 0.001 wt % to 99.999 wt % in the solid, and the additive may be contained in an amount of 0.001 wt % to 99.999 wt % in the solid. In an implementation, the additive may be contained in an amount of 0.1 wt % to 99 wt %, or 5 wt % to 95 wt %. For example, when the additive is a polymeric adsorbent, the additive may be contained in an amount of 5 wt % to 95 wt % with respect to the entire rinse material composition.

When the content of the solid is less than the above range, the improvement of LER and LWR may be small. When the content of the solid is larger than the above range, additional time may be required to remove the solid during an etching process.

The method of forming a target pattern using the rinse material composition according to an implementation may provide a resist pattern having a fine line width and reduced collapse by using an organometallic oxide as a photosensitive resist.

As semiconductor processes for manufacturing various electronic devices have been scaled down in recent years, lithography used in semiconductor processes requires patterning technology with a line width of 35 nm or less, 20 nm or less, or 15 nm or less.

However, to process (for example, etch) lower features using lithography, a thickness of the resist pattern is still required to be at least a minimum level. Accordingly, an aspect ratio of the resist pattern is rapidly increasing. In this case, when the aspect ratio of the resist pattern is high, the resist pattern may collapse during a process of forming the resist pattern. The collapse of the resist pattern may occur when a cleaning solution (for example, ultrapure water) is used during a process of cleaning the resist pattern formed with a developer and then spin-drying the resist pattern. This is because the cleaning solution has a high surface tension between resist patterns, resulting in a force that pulls the resist patterns sideways, for example, a capillary force based on a capillary phenomenon.

However, when the aspect ratio of the resist pattern is low when the resist pattern is used as a mask in a subsequent process to process a lower target feature layer, for example, when a height of the photoresist is significantly small, the resist pattern may be broken. The pattern breakage may also occur when etch resistance of the resist pattern is insufficient.

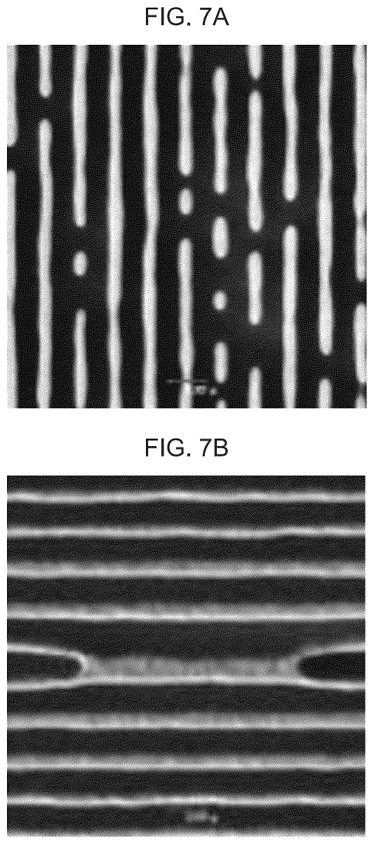

The resist pattern breakage or collapse may be seen in the images illustrated in FIGS. 7A and 7B. FIGS. 7A and 7B are images captured when a resist pattern is broken or collapsed in a process of forming a resist pattern according to the related art.

In contrast, implementations provide a patterning technology using EUV as a fine line width, and provide a method of forming a pattern, which is capable of forming a resist pattern having a minimum thickness, for example, 10 nm or less, without the collapse of the resist pattern during a process of forming the resist pattern.

In an implementation, in addition to controlling collapse of a resist pattern during a process of forming the resist pattern, a rinse material composition may also increase a process margin in an etching process by mitigating the surface roughness of a developed resist pattern. Accordingly, in the process of forming the resist pattern according to an implementation, a thickness (for example, height) of a finally obtained resist pattern may be increased compared to the related art. In addition, LER and/or LWR of the resist pattern may be improved, and local critical dimension uniformity (LCDU) of the resist pattern may also be improved. The improvement of LER and LWR and/or LCDU may allow a dose of EUV exposure to be maintained or increased.

Additionally, in an implementation, a resist pattern may be formed in an area exposed during first exposure to prevent tone reversal from occurring. A resist pattern according to an implementation, in which tone reversal does not occur, may be formed to prevent defects that may occur in a process in which tone reversal occurs, for example, a resist pattern is formed insufficiently vertically, an upper side of the resist pattern has a rounded profile, or a line width of the resist pattern varies depending on a location thereof during an etching process.

As set forth above, according to implementations, a rinse material composition used in a process of forming a pattern using lithography may be provided. The rinse material composition may prevent collapse of a resist pattern and improve line width roughness or line edge roughness of the resist pattern.

In addition, according to implementations, a method of forming a pattern using the rinse material composition may be provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While implementations have been shown and described above, it will be apparent to those skilled in the art that modifications and variations could be made without departing from the scope of the present disclosure as defined by the appended claims.

What is claimed is:

1. A rinse material composition used in a process of forming a pattern using lithography, the rinse material composition comprising:
a dry development rinse material (DDRM) compound designed to form hydrogen bonds, van der Waals bonds, coordination bonds, or ionic bonds with photosensitive crosslinkable molecules containing an organometallic material of a resist pattern; and
a solvent in which the DDRM compound is dissolved.

2. The rinse material composition of claim 1, wherein DDRM molecules constituting the DDRM compound comprise:
a body comprising a substituted or unsubstituted linear or cyclic hydrocarbon compound having 4 to 100 carbon atoms; and
at least one hydrophilic group linked to the body and designed to form hydrogen bonds, van der Waals bonds, coordination bonds, or ionic bonds with the photosensitive crosslinkable molecules.

3. The rinse material composition of claim 2, wherein
the hydrophilic group is at least one of a hydroxyl group, a carboxyl group, a thiol group, an amino group, or an amide group.

4. The rinse material composition of claim 2, wherein
the DDRM compound comprises at least one of a carboxylic acid, a sulfonic acid, sulfuric acid, a phosphonic acid, a phosphinic acid, a phosphinic acid anhydride, a carboxylate, a phosphonate, an amine, or a thiol.

5. The rinse material composition of claim 3, wherein
the substituted or unsubstituted linear or cyclic hydrocarbon compound comprises at least one of a carbonyl group or an ether group therein.

6. The rinse material composition of claim 5, wherein
the substituted or unsubstituted linear or cyclic hydrocarbon compound is a dendrimer comprising at least one of a hydroxyl group or a carboxyl group at an end portion of the body.

7. The rinse material composition of claim 1, wherein
the DDRM compound is provided in an amount of 0.5 weight percent (wt %) to 10 wt % with respect to a total amount of the rinse material composition.

8. The rinse material composition of claim 1, further comprising:
an additive, wherein the additive comprises at least one of a surfactant or a polymeric adsorbent.

9. The rinse material composition of claim 8, wherein the DDRM compound and the additive are provided in an amount of 0.5 weight percent (wt %) to 10 wt % with respect to a total amount of the rinse material composition.

10. The rinse material composition of claim 9, wherein
the DDRM compound and the additive constitute a solid, except for the solvent, of the rinse material composition, and
the DDRM compound are provided in an amount of 0.001 wt % to 99.999 wt % within the solid.

11. A method of forming a pattern, the method comprising:
forming a target layer on a substrate;
forming a resist layer on the target layer;
exposing a first area of the resist layer;
developing the resist layer to form a resist pattern in the first area;
providing a rinse material composition to the resist pattern;
baking the rinse material composition;
dry-etching the baked rinse material composition to be removed from a second area, distinct from the first area; and
treating the target layer using the resist pattern as a mask,
wherein the resist layer comprises photosensitive crosslinkable molecules containing an organometallic material, and the rinse material composition comprises a dry development rinse material (DDRM) compound, designed to form hydrogen bonds, van der Waals bonds, coordination bonds, or ionic bonds with the photosensitive crosslinkable molecules, and a solvent in which the DDRM compound is dissolved.

12. The method of claim 11, wherein
DDRM molecules constituting the DDRM compound comprise:
a body comprising a substituted or unsubstituted linear or cyclic hydrocarbon compound having 4 to 100 carbon atoms; and
at least one hydrophilic group linked to the body and designed to form hydrogen bonds, van der Waals bonds, coordination bonds, or ionic bonds with the photosensitive crosslinkable molecules.

13. The method of claim 11, wherein
exposing the first area of the resist layer is performed using extreme ultraviolet light.

14. The method of claim 11, wherein
the resist layer is formed to have a thickness of 100 nanometers or less.

15. The method of claim 11, further comprising:
performing a first baking process on the resist layer before exposing the first area of the resist layer; and
performing a second baking process on the resist layer after exposing the first area of the resist layer.

16. The method of claim 11, further comprising:
performing a cleaning process to clean the resist pattern with a rinse solution after developing the resist layer before providing the rinse material composition.

17. The method of claim 11, wherein
a height of the rinse material composition is greater than a height of the resist pattern when the rinse material composition is applied to the resist pattern.

18. The method of claim 11, wherein
dry-etching the rinse material composition is performed using an oxygen-based plasma.

19. The method of claim 11, wherein
treating the target layer comprises etching the target layer using the resist pattern as a mask.

20. A method of forming a resist pattern, the method comprising:
forming a resist layer on a substrate;
exposing a first area of the resist layer;
applying a developer to the resist layer to develop the resist layer and form a resist pattern in the first area;
providing a rinse material composition to the resist pattern;
baking the rinse material composition; and
dry-etching the baked rinse material composition to be removed in a second area, distinct from the first area, and to form a resist pattern in the first area,
wherein the resist layer comprises photosensitive crosslinkable molecules containing an organometallic material, and
wherein the rinse material composition comprises a dry development rinse material (DDRM) compound, designed to form hydrogen bonds, van der Waals bonds, coordination bonds, or ionic bonds with the photosensitive crosslinkable molecules, and a solvent in which the DDRM compound is dissolved.
